(19) United States
(12) Patent Application Publication
(10) Pub. No.: US 2018/0019121 A1
(43) Pub. Date: Jan. 18, 2018

(54) METHOD AND MATERIAL FOR CMOS CONTACT AND BARRIER LAYER

(71) Applicant: Applied Materials, Inc., Santa Clara, CA (US)

(72) Inventors: Xinyu BAO, Fremont, CA (US); Chun YAN, San Jose, CA (US); Zhiyuan YE, San Jose, CA (US); Errol Antonio C. SANCHEZ, Tracy, CA (US); David K. CARLSON, San Jose, CA (US)

(21) Appl. No.: 15/631,185

(22) Filed: Jun. 23, 2017

Related U.S. Application Data
(60) Provisional application No. 62/363,617, filed on Jul. 18, 2016.

(51) Int. Cl. H01L 21/02; H01L 29/24; H01L 29/78

(52) U.S. Cl. CPC H01L 21/02521; H01L 29/7848; H01L 21/0262; H01L 29/24

(57) ABSTRACT

The present disclosure generally relate to methods for forming an epitaxial layer on a semiconductor device, including a method of forming a tensile-stressed silicon antimony layer. The method includes heating a substrate disposed within a processing chamber, wherein the substrate comprises silicon, and exposing a surface of the substrate to a gas mixture comprising a silicon-containing precursor and an antimony-containing precursor to form a silicon antimony alloy having an antimony concentration of 5×10²⁰ to 5×10²¹ atoms per cubic centimeter or greater on the surface.

### CROSS-REFERENCE TO RELATED APPLICATIONS

This application claims priority to U.S. provisional patent application Ser. No. 62/363,617, filed Jul. 18, 2016, which is herein incorporated by reference.

### FIELD

Implementations of the disclosure generally relate to the field of semiconductor manufacturing processes and devices, more particularly, to methods for epitaxial growth of a silicon material on an epitaxial film.

### BACKGROUND

Microelectronic devices are fabricated on a semiconductor substrate as integrated circuits in which various conductive layers are interconnected with one another to permit electronic signals to propagate within the device. An example of such a device is a complementary metal-oxide-semiconductor (CMOS) field effect transistor (FET) or MOSFET. Typical MOSFET transistors may include p-channel (PMOS) transistors and n-channel MOS (NMOS) transistors, depending on the dopant conductivity types, whereas the PMOS has a p-type channel, i.e., holes are responsible for conduction in the channel, and the NMOS has an n-type channel, i.e., the electrons are responsible for conduction in the channel.

The amount of current that flows through the channel of a MOS transistor is directly proportional to a mobility of carriers in the channel. The use of high mobility MOS transistors enables more current to flow and consequently faster circuit performance. Mobility of the carriers in the channel of an MOS transistor can be increased by producing a mechanical stress in the channel. A channel under compressive strain, for example, a silicon-germanium channel layer grown on silicon, has significantly enhanced hole mobility to provide a pMOS transistor. A channel under tensile strain, for example, a thin silicon channel layer grown on relaxed silicon-germanium, achieves significantly enhanced electron mobility to provide an nMOS transistor.

An nMOS transistor channel under tensile strain can also be provided by forming one or more heavily phosphorus-doped silicon epitaxial layers or heavily carbon-doped silicon epitaxial layers. Heavily doped silicon epitaxial layers can be used to reduce the contact resistance. Contact resistance becomes the major limiting factor of transistor performance in the recent and future nodes due to the fact that the manufacturing conditions may be different for epitaxy having different dopants and dopant concentrations. For example, diffusion control of high strain Si:P epitaxy when activating and to achieve high levels of dopants (e.g., greater than 4×10²¹ atoms/cm³) has been a major challenge due to morphology degradation.

Therefore, improved methods for providing tensile stress in the channel and providing low series resistance are in the art.

### SUMMARY

The present disclosure generally relates to methods for forming a tensile-stressed silicon antimony layer. In one implementation, the method includes heating a substrate disposed within a processing chamber, wherein the substrate comprises silicon, and exposing a surface of the substrate to a gas mixture comprising a silicon-containing precursor and an antimony-containing precursor to form a silicon antimony alloy having an antimony concentration of 5×10²⁰ to 5×10²¹ atoms per cubic centimeter or greater on the surface.

In another implementation, a method includes positioning a semiconductor substrate in a processing chamber, wherein the substrate comprises a source/drain region, exposing the substrate to a silicon-containing precursor and an antimony-containing precursor to form a silicon antimony alloy having an antimony concentration of 5×10²⁰ to 5×10²¹ atoms per cubic centimeter or greater on the source/drain region, wherein the silicon antimony alloy has a carbon concentration of about 1×10¹⁷ atoms per cubic centimeter or greater, and forming a transistor channel region on the silicon antimony alloy.

In yet another implementation, a structure is provided. The structure includes a substrate comprising a source region and a drain region, and a transistor channel region adjacent the source region and the drain region, and a silicon antimony alloy disposed between the transistor channel region and the source region and the drain region, the silicon antimony alloy having an antimony concentration of 5×10²⁰ to 5×10²¹ atoms per cubic centimeter or greater and a carbon concentration of about 1×10¹⁷ atoms per cubic centimeter or greater.

### BRIEF DESCRIPTION OF THE DRAWINGS

Implementations of the present invention, briefly summarized above and discussed in greater detail below, can be understood by reference to the illustrative implementations of the invention depicted in the appended drawings. It is to be noted, however, that the appended drawings illustrate only typical implementations of this invention and are therefore not to be considered limiting of its scope, for the invention may admit to other equally effective implementations.

FIG. 1 is a flow chart illustrating a method of forming an epitaxial layer according to one implementation of the present disclosure.

FIG. 2 illustrates a structure manufactured according to the method of FIG. 1.

FIG. 3 is a flow chart illustrating a method of forming an epitaxial layer according to another implementation of the present disclosure.

To facilitate understanding, identical reference numerals have been used, where possible, to designate identical elements that are common to the figures. The figures are not drawn to scale and may be simplified for clarity. It is contemplated that elements and features of one implementation may be beneficially incorporated in other implementations without further recitation.

### DETAILED DESCRIPTION

Implementations of the present disclosure generally provide selective epitaxy processes for silicon, germanium, or germanium-tin layer having high antimony (Sb) concentration. In one exemplary implementation, the selective epitaxy process uses a gas mixture comprising silicon source and an arsenic dopant source, and is performed at a chamber pressure about 20 Torr to 400 Torr and reduced process temperatures below 800 degrees Celsius to allow for formation of a tensile-stressed epitaxial silicon layer having an antimony concentration of 5×10²⁰ to 5×10²¹ atoms per cubic centimeter or greater. The antimony concentration of about 5×10²⁰ to 5×10²¹ atoms per cubic centimeter or greater results in increased carrier mobility and improved device performance for MOSFET structures. Various implementations are discussed in more detail below.

Implementations of the present disclosure may be practiced in the CENTURA® RP Epi chamber available from Applied Materials, Inc., of Santa Clara, Calif. It is contemplated that other chambers, including those available from other manufacturers, may be used to practice implementations of the disclosure.

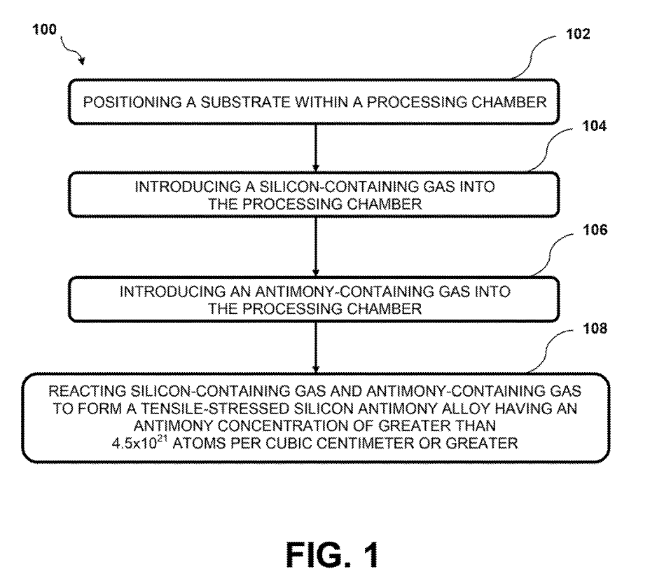

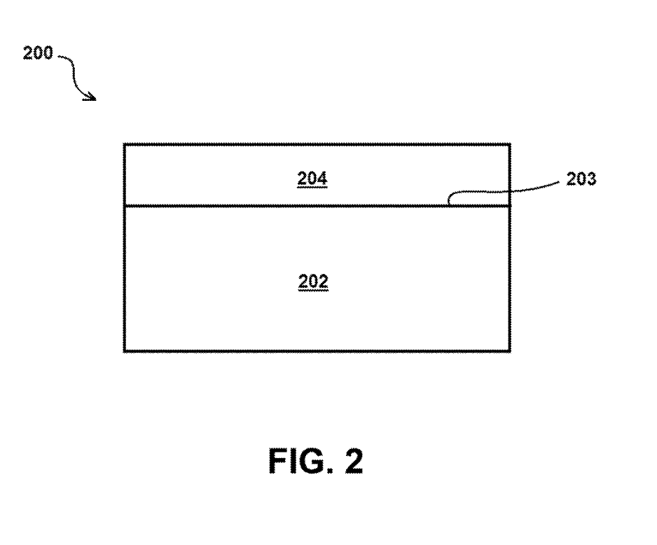

FIG. 1 is a flow chart 100 illustrating a method of forming an epitaxial layer according to one implementation of the present disclosure. FIG. 2 illustrates a structure 200 manufactured according to method of FIG. 1. At box 102, a substrate 202 is positioned within a processing chamber. The term “substrate” used herein is intended to broadly cover any object or material having a surface onto which a material layer can be deposited. A substrate may include a bulk material such as silicon (e.g., single crystal silicon which may include dopants) or may include one or more layers overlying the bulk material. The substrate may be a planar substrate or a patterned substrate. Patterned substrates are substrates that may include electronic features formed into or onto a processing surface of the substrate. The substrate may contain monocrystalline surfaces and/or one secondary surface that is non-monocrystalline, such as polycrystalline or amorphous surfaces. Monocrystalline surfaces may include the bare crystalline substrate or a deposited single crystal layer usually made from a material such as silicon, germanium, silicon germanium or silicon carbon. Polycrystalline or amorphous surfaces may include dielectric materials, such as oxides or nitrides, specifically silicon oxide or silicon nitride, as well as amorphous silicon surfaces.

Positioning the substrate in the processing chamber may include adjusting one or more reactor conditions, such as temperature, pressure, and/or carrier gas (e.g., Ar, N₂, H₂, or He) flow rate, to conditions suitable for film formation. For example, in some implementations, the temperature in the processing chamber may be adjusted so that a reaction region formed at or near an exposed silicon surface of the substrate, or that the surface of the substrate itself, is about 850 degrees Celsius or less, for example about 750 degrees Celsius or less. In one example, the substrate is heated to a temperature of about 200 degrees Celsius to about 800 degrees Celsius, for example about 250 degrees Celsius to about 650 degrees Celsius, such as about 300 degrees Celsius to about 600 degrees Celsius. It is possible to minimize the thermal budget of the final device by heating the substrate to the lowest temperature sufficient to thermally decompose process reagents and deposit a layer on the substrate. The pressure in the processing chamber may be adjusted so that the reaction region pressure is within range of about 1 to about 760 Torr, for example about 90 to about 300 Torr. In some implementations, a carrier (e.g., nitrogen) gas may be flowed into the processing chamber at a flow rate of approximately 10 to 40 SLM (standard liters per minute). However, it will be appreciated that in some implementations, a different carrier/diluent gas may be employed, a different flow rate may be used, or that such gas(es) may be omitted.

At box 104, a silicon-containing precursor is introduced into the processing chamber. Suitable silicon-containing precursors may be non-carbon silicon source gases or carbon-containing silicon source gases. For example, the silicon-containing precursors may be silanes, halogenated silanes, organosilanes, or any combinations thereof. Silanes may include silane (SiH₄) and higher silanes with the empirical formula SiₓH₍₂ₓ₊₂₎, such as disilane (Si₂H₆), trisilane (Si₃H₈), and tetrasilane (Si₄H₁₀), or other higher order silanes such as polychlorosilane. Halogenated silanes may include compounds with the empirical formula X′_{y}SiₓH_{(2x+2-y)}, where X′=F, Cl, Br or I, such as hexachlorodisilane (Si₂Cl₆), tetrachlorosilane (SiCl₄), dichlorosilane (Cl₂SiH₂) and trichlorosilane (Cl₃SiH). Organosilanes may include compounds with the empirical formula R_{y}SiₓH_{(2x+2-y)}, where R=methyl, ethyl, propyl or butyl, such as methylsilane ((CH₃)SiH₃), dimethylsilane ((CH₃)₂SiH₂), ethylsilane ((CH₃CH₂)SiH₃), methyldisilane ((CH₃)Si₂H₅), dimethyldisilane ((CH₃)₂Si₂H₄) and hexamethyldisilane ((CH₃)₆Si₂).

In one exemplary example where a non-carbon silicon source gas is used, the non-carbon silicon source gas may be flowed into the processing chamber at a flow rate of approximately 5 sccm to about 100 sccm, for example about 10 sccm to about 35 sccm, such as about 15 sccm to about 25 sccm, for example about 20 sccm. In some implementations, the non-carbon silicon source gas may be flowed into the processing chamber at a flow rate of about 300 sccm to about 1500 sccm, for example about 800 sccm.

At box 106, an antimony-containing precursor is introduced into the processing chamber. Suitable antimony-containing precursors may be non-carbon antimony source gases or carbon-containing antimony source gases. The use of carbon-containing antimony source gases adds additional carbon to the epitaxial film to provide additional stress or diffusion block. In various implementations, the antimony-containing precursor may include stibine (SbH₃), antimony trichloride (SbCl₃), antimony tetrachloride (SbCl₄), antimony pentachloride (SbCl₅), triphenylantimony ((C₆H₅)₃Sb), antimony trihydide (SbH₃), antimonytrioxide (Sb₂O₃), antimony pentoxide (Sb₂O₅), antimony trifluoride (SbF₃), antimony tribromide (SbBr₃), antimonytriiodide (SbI₃), antimony pentafluoride (SbF₅), Triethyl antimony (TESb) and trimethyl antimony (TMSb).

In one exemplary example where a non-carbon antimony source gas is used, the non-carbon antimony source gas may be introduced into the processing chamber at a flow rate of approximately 10 sccm to about 2500 sccm, for example about 500 sccm to about 1500 sccm. A non-reactive carrier/diluent gas (e.g., nitrogen or argon) and/or a reactive carrier/diluent gas (e.g., hydrogen) may be used to supply the antimony-containing precursor to the processing chamber. For example, antimony may be diluted in hydrogen at a ratio of about one percent. The carrier/diluent gas may have a flow rate from about 1 SLM to about 100 SLM, such as from about 3 SLM to about 30 SLM.

It is contemplated that boxes 104 and 106 may occur simultaneously, substantially simultaneously, or in any desired order. In addition, while antimony-containing precursor is discussed in this disclosure, it is contemplated that any gas consisting of dopant atoms having diffusion coefficients less than the diffusion coefficient of the phosphorous atoms in silicon may be used induce stress in the silicon lattice structure. For example, an arsenic-containing precursor, such as Tertiary butyl arsine (TBAs) or arsine (AsH₃), may be used to replace, or in addition to, the antimony-containing precursor.

If desired, one or more dopant gases may be introduced into the processing chamber to provide the epitaxial layer with desired conductive characteristic and various electric characteristics, such as directional electron flow in a controlled and desired pathway required by the electronic device. Exemplary dopant gas may include, but are not limited to phosphorous, boron, germanium, gallium, or aluminum, depending upon the desired conductive characteristic of the deposited epitaxial layer.

At box 108, the mixture of silicon-containing precursor and the antimony-containing precursor is thermally reacted to form a tensile-stressed silicon antimony alloy having an antimony concentration of greater than 5×10²⁰ to 5×10²¹ atoms per cubic centimeter or greater, for example 5×10²² atoms per cubic centimeter, within an acceptable tolerance of ±3%.

The silicon source and the antimony source may react in a reaction region of the processing chamber so that the silicon antimony alloy 204 is epitaxially formed on a surface 203 of the substrate 202. The silicon antimony alloy 204 may have a thickness of about 250 Å to about 800 Å, for example about 500 Å. Not wishing to be bound by theory, it is believed that at an antimony concentration of about 5×10²⁰ atoms per cubic centimeter or greater, for example about 5×10²¹ atoms per cubic centimeter or greater, the deposited epitaxial film is not purely a silicon film doped with antimony, but rather, that the deposited film is an alloy between silicon and silicon antimony (e.g., pseudocubic Si₃Sb₄). Silicon antimony alloy generates stabilized vacancy in silicon lattice that would expel silicon atoms from the lattice structure, which in turn collapses the silicon lattice structure and thus forms a zoned stress in the epitaxial film. A tensile-stressed epitaxial silicon layer having an antimony concentration of 5×10²⁰ atoms per cubic centimeter or greater can improve transistor performance because stress distorts (e.g., strains) the semiconductor crystal lattice, and the distortion, in turn, affects charge transport properties of the semiconductor. As a result, carrier mobility in the transistor channel region is increased. By controlling the magnitude of stress in a finished device, manufacturers can increase carrier mobility and improve device performance.

During the epitaxy process, the temperature within the processing chamber is maintained at about 400 degrees Celsius to about 800 degrees Celsius, for example about 450 degrees Celsius to about 700 degrees Celsius, such as about 550 degrees Celsius to about 625 degrees Celsius.

The pressure within the processing chamber is maintained at about 1 Torr or greater, for example, about 10 Torr or greater, such as about 20 Torr to about 400 Torr. It is contemplated that pressures greater than about 400 Torr may be utilized when low pressure deposition chambers are not employed. In contrast, typical epitaxial growth processes in low pressure deposition chambers maintain a processing pressure of about 10 Torr to about 100 Torr and a processing temperature greater than 600 degrees Celsius. However, it has been observed that by increasing the pressure to about 150 Torr or greater, for example about 300 Torr or greater, the deposited epitaxial film can be formed with a greater antimony concentration (e.g., about 1×10²⁰ atoms per cubic centimeter to about 5×10²¹ atoms per cubic centimeter) as compared to lower pressure epitaxial growth processes.

It should be noted that the concept described in implementations of the present disclosure is also applicable to other materials that may be used in logic and memory applications. Some example may include SiGeAs, Ge, GeP, SiGeP, SiGeB, Si:CP, GeSn, GeP, GeB, or GeSnB that are formed as an alloy. If a germanium-containing layer is desired, a gas mixture comprising a germanium-containing precursor may be introduced into the processing chamber. In such a case, the gas mixture may contain the silicon-containing precursor and the antimony-containing precursor discussed above. Suitable germanium-containing precursor may include, but is not limited to germane (GeH₄), digermane (Ge₂H₆), trigermane (Ge₃H₈), chlorinated germane gas such as germanium tetrachloride (GeCl₄), dichlorogermane (GeH₂Cl₂), trichlorogermane (GeHCl₃), hexachlorodigermane (Ge₂Cl₆), or a combination of any two or more thereof. Any suitable halogenated germanium compounds may also be used. In one exemplary implementation, digermane (Ge₂H₆) is used. In any case, the doping level may exceed solid solubility in the epitaxial layer, for example above 5×10²⁰, or about 1% or 2% dopant level.

In addition, although epitaxy process is discussed in this disclosure, it is contemplated that other process, such as Sb implantation process, may also be used to form a tensile-stressed silicon antimony or germanium antimony layer. In case where implantation process is utilized to implant Sb into silicon, an annealing process running at about 600 degrees Celsius or higher, for example about 950 degrees Celsius, may be performed after the implantation process to stabilize or repair any damages in the lattice structure caused by the implantation process. Anneal processes can be carried out using laser anneal processes, spike anneal processes, or rapid thermal anneal processes. The lasers may be any type of laser such as gas laser, excimer laser, solid-state laser, fiber laser, semiconductor laser etc., which may be configurable to emit light at a single wavelength or at two or more wavelengths simultaneously. The laser anneal process may take place on a given region of the substrate for a relatively short time, such as on the order of about one second or less. In one implementation, the laser anneal process is performed on the order of millisecond. Millisecond annealing provides improved yield performance while enabling precise control of the placement of atoms in the deposited epitaxial layer. Millisecond annealing also avoids dopant diffusion or any negative impact on the resistivity and the tensile strain of the deposited layer.

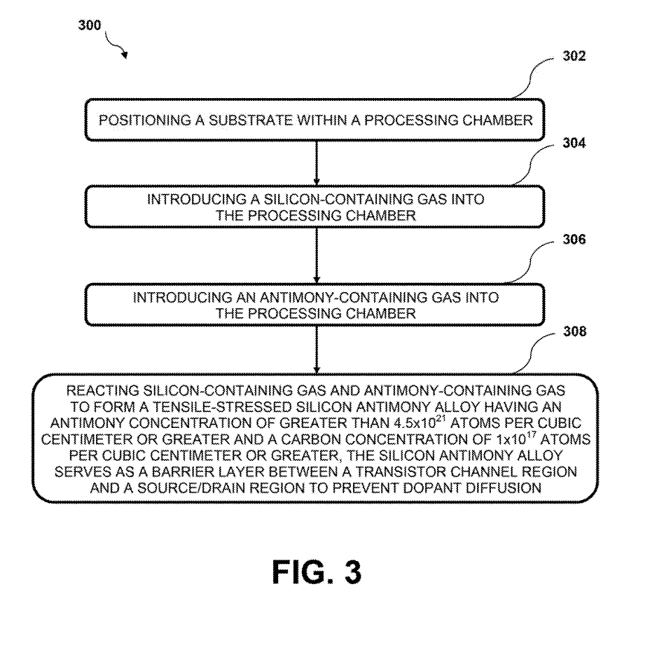

FIG. 3 is a flow chart 300 illustrating a method of forming an epitaxial layer according to another implementation of the present disclosure. At box 302, a substrate is positioned within a processing chamber. One or more reactor conditions may be adjusted in a similar manner as discussed above with respect to box 102.

At box 304, a silicon-containing precursor is introduced into the processing chamber. Suitable silicon-containing precursor may include, but is not limited to, silanes, halogenated silanes, or combinations thereof. Silanes may include silane (SiH₄) and higher silanes with the empirical formula SiₓH₍₂ₓ₊₂₎, such as disilane (Si₂H₆), trisilane (Si₃H₈), and tetrasilane (Si₄H₁₀). Halogenated silanes may include monochlorosilane (MCS), dichlorosilane (DCS), trichlorosilane (TCS), tetrachlorosilane (STC), hexachlorodisilane (HCDS), octachlorotrisilane (OCTS), or any combination thereof. In one implementation, the silicon-containing precursor is disilane. In another implementation, the silicon source comprises TCS. In yet another implementation, the silicon source comprises TCS and DCS. In one example where disilane is used, disilane may be flowed into processing chamber at a flow rate of approximately 200 sccm to about 1500 sccm, for example about 500 sccm to about 1000 sccm, such as about 700 sccm to about 850 sccm, for example about 800 sccm.

In some cases where the substrate contains monocrystalline surfaces and one secondary surface that is non-monocrystalline, such as polycrystalline or amorphous surfaces that may include dielectric surfaces, halogenated silanes such as TCS may be first flowed into the processing chamber and served as a pre-treatment gas to passivate the dielectric surfaces of the substrate, and then while flowing the halogenated silanes, flowing a different process precursor(s) such as DCS into the processing chamber.

At box 306, an antimony-containing precursor is introduced into the processing chamber. Suitable antimony-containing precursor may include stibine (SbH₃), antimony trichloride (SbCl₃), antimony tetrachloride (SbCl₄), antimony pentachloride (SbCl₅), triphenylantimony ((C₅H₅)₃Sb), antimony trihydide (SbH₃), antimonytrioxide (Sb₂O₃), antimony pentoxide (Sb₂O₅), antimony trifluoride antimony tribromide (SbBr₃), antimonytriiodide (SbI₃), antimony pentafluoride (SbF₅), Triethyl antimony (TESb) and trimethyl antimony (TMSb). In one implementation, TESb or TMSb is introduced into the processing chamber at a flow rate of approximately 10 sccm to about 1000 sccm, such as about 20 sccm to about 100 sccm, for example about 75 sccm to about 85 sccm. In various embodiments of this disclosure, the input Sb/Si molar ratio may be about 0.001 to about 0.1.

It is contemplated that boxes 304 and 306 may occur simultaneously, substantially simultaneously, or in any desired order. In addition, while antimony-containing precursor is discussed in this disclosure, it is contemplated that any gas consisting of dopant atoms having diffusion coefficients less than the diffusion coefficient of the phosphorous atoms in silicon may be used induce stress in the silicon lattice structure. For example, an arsenic-containing precursor, such as Tertiary butyl arsine (TBAs) or arsine (AsH₃), may be used to replace, or in addition to, the antimony-containing precursor.

If desired, one or more dopant gases may be introduced into the processing chamber to provide the epitaxial layer with desired conductive characteristic and various electric characteristics, such as directional electron flow in a controlled and desired pathway required by the electronic device. Exemplary dopant gas may include, but are not limited to phosphorous, boron, gallium, or aluminum, depending upon the desired conductive characteristic of the deposited epitaxial layer.

At box 308, the mixture of silicon-containing precursor and the antimony-containing precursor is thermally reacted to form a tensile-stressed silicon antimony alloy having an antimony concentration of 5×10²⁰ to 5×10²¹ atoms per cubic centimeter or greater, within an acceptable tolerance of ±3%. Particularly, the silicon antimony alloy contains carbons from TESb or TMSb. In one implementation, the silicon antimony alloy has a carbon concentration of about 1×10¹⁷ atoms per cubic centimeter or greater, for example about 1×10²⁰ atoms per cubic centimeter. The deposited silicon antimony alloy may have a thickness of about 250 Å to about 800 Å, for example about 400 Å to about 600 Å. If the silicon antimony alloy is used as a diffusion barrier, the thickness of the deposited silicon antimony alloy may be less than about 100 Å, for example about 30 Å to about 80 Å.

In this disclosure, the heavily Sb doped silicon layer (SiSb) layer or silicon antimony alloy may serve as a contact layer in source and/or drain region with less problems with dopant diffusion to the channel layer. Additionally or alternatively, the heavily Sb doped silicon layer (SiSb) layer or silicon antimony alloy may serve as a barrier layer presented between a transistor channel region and source/drain regions in a semiconductor device, such as a metal-oxide-semiconductor field-effect transistor (MOSFET) or a FinFET (Fin field-effect transistor) in which the channel connecting the source and drain regions is a thin “fin” jutting out of a substrate. This is because carbons in the deposited epitaxial film can prevent or slow down diffusion of phosphorus (or other dopants) from source/drain regions into the channel region during a high temperature (e.g., above 800 degrees Celsius) operation. Such dopant diffusion disadvantageously contributes to leakage currents and poor breakdown performance. The barrier layer may be used for other contact layers such as Si:CP and Si:P.

Similarly, during the epitaxy process, the temperature within the processing chamber is maintained at about 400 degrees Celsius to about 800 degrees Celsius, for example about 600 degrees Celsius to about 750 degrees Celsius, such as about 625 degrees Celsius to about 700 degrees Celsius. The pressure within the processing chamber is maintained at about 20 Torr to about 400 Torr, for example, about 100 Torr to about 350 Torr, depending upon the silicon source used. In addition, by increasing the pressure to about 150 Torr or greater, for example about 300 Torr or greater, the deposited epitaxial film can be formed with a greater antimony concentration (e.g., about 5×10²⁰ atoms per cubic centimeter or above) as compared to lower pressure epitaxial growth processes.

Benefits of the present disclosure include a tensile-stressed silicon antimony layer having an antimony doping level of greater than 5×10²⁰ to 5×10²¹ atoms per cubic centimeter or greater to improve transistor performance. Heavily antimony doped silicon can result in significant tensile strain in silicon or other materials suitable for use in logic and memory applications such as silicon. The increased stress distorts or strains the semiconductor crystal lattice, and the distortion, in turn, affects charge transport properties of the semiconductor. As a result, carrier mobility is increased and device performance is therefore improved. In some implementations, a heavily antimony doped silicon may contain carbon at a concentration of 1×10¹⁷ atoms per cubic centimeter or greater to prevent diffusion of phosphorus (or other dopants) from source/drain regions into a channel region during a high temperature operation. Therefore, leakage current occurred at the channel region is minimized or avoided. Compared to As or P, the Sb precursor and byproducts are non-toxic.

While the foregoing is directed to implementations of the present invention, other and further implementations of the invention may be devised without departing from the basic scope thereof.

1. A method of forming a tensile-stressed silicon antimony layer, comprising:
heating a substrate disposed within a processing chamber, wherein the substrate comprises silicon; and
exposing a surface of the substrate to a gas mixture comprising a silicon-containing precursor and an antimony-containing precursor to form a silicon antimony alloy having an antimony concentration of 5×10²⁰ to 5×10²¹ atoms per cubic centimeter or greater on the surface.

2. The method of claim 1, wherein the silicon-containing precursor comprises silanes, halogenated silanes, organosilanes, or combinations thereof.

3. The method of claim 2, wherein the silanes comprises silane (SiH₄), disilane (Si₂H₆), trisilane (Si₃H₈), tetrasilane (Si₄H₁₀), or polychlorosilane.

4. The method of claim 2, wherein the halogenated silanes comprise hexachlorodisilane (Si₂Cl₆), tetrachlorosilane (SiCl₄), dichlorosilane (Cl₂SiH₂) or trichlorosilane (Cl₃SiH).

5. The method of claim 1, wherein the antimony-containing precursor comprises stibine (SbH₃), antimony trichloride (SbCl₃), antimony tetrachloride (SbCl₄), antimony pentachloride (SbCl₅), triphenylantimony ((C₆H₅)₃Sb), antimony trihydide (SbH₃), antimonytrioxide (Sb₂O₃), antimony pentoxide (Sb₂O₅), antimony trifluoride (SbF₃), antimony tribromide (SbBr₃), antimonytriiodide (SbI₃), antimony pentafluoride (SbF₅), Triethyl antimony (TESb), or trimethyl antimony (TMSb).

6. The method of claim 1, wherein the gas mixture further comprises a germanium-containing precursor selected from the group consisting of germane (GeH₄), digermane (Ge₂H₆), trigermane (Ge₃H₈), germanium tetrachloride (GeCl₄), dichlorogermane (GeH₂Cl₂), trichlorogermane (GeHCl₃), and hexachlorodigermane (Ge₂Cl₆).

7. The method of claim 5, wherein the antimony-containing precursor comprises Triethyl antimony (TESb) or trimethyl antimony (TMSb).

8. The method of claim 1, wherein exposing a surface of the substrate to a gas mixture comprises maintaining a temperature within the processing chamber of about 450 degrees Celsius to about 700 degrees Celsius.

9. The method of claim 1, wherein the pressure within the processing chamber is maintained at about 20 Torr to about 400 Torr.

10. A method of processing a substrate, comprising:
positioning a semiconductor substrate in a processing chamber, wherein the substrate comprises a source/drain region;
exposing the substrate to a silicon-containing precursor and an antimony-containing precursor to form a silicon antimony alloy having an antimony concentration of 5×10²⁰ to 5×10²¹ atoms per cubic centimeter or greater on the source/drain region, wherein the silicon antimony alloy has a carbon concentration of about 1×10¹⁷ atoms per cubic centimeter or greater; and
forming a transistor channel region on the silicon antimony alloy.

11. The method of claim 10, wherein the silicon-containing precursor comprises silane (SiH₄), disilane (Si₂H₆), trisilane (Si₃H₈), tetrasilane (Si₄H₁₀), monochlorosilane (MCS), dichlorosilane (DCS), trichlorosilane (TCS), hexachlorodisilane (HCDS), octachlorotrisilane (OCTS), silicon tetrachloride (STC), or any combination thereof.

12. The method of claim 10, wherein the antimony-containing precursor comprises stibine (SbH₃), antimony trichloride (SbCl₃), antimony tetrachloride (SbCl₄), antimony pentachloride (SbCl₅), triphenylantimony ((C₆H₅)₃Sb), antimony trihydide (SbH₃), antimonytrioxide (Sb₂O₃), antimony pentoxide (Sb₂O₅), antimony trifluoride (SbF₃), antimony tribromide (SbBr₃), antimonytriiodide (SbI₃), antimony pentafluoride (SbF₅), Triethyl antimony (TESb), or trimethyl antimony (TMSb).

13. The method of claim 10, wherein the silicon-containing precursor is disilane and the antimony-containing precursor is SbH₃.

14. The method of claim 10, wherein the silicon antimony alloy has a carbon concentration of 1×10¹⁷ to 1×10²⁰ atoms per cubic centimeter.

15. A structure, comprising:
a substrate comprising a source region and a drain region, and a transistor channel region adjacent the source region and the drain region; and
a silicon antimony alloy disposed between the transistor channel region and the source region and the drain region, the silicon antimony alloy having an antimony concentration of 5×10²⁰ to 5×10²¹ atoms per cubic centimeter or greater and a carbon concentration of about 1×10¹⁷ atoms per cubic centimeter or greater.

16. The structure of claim 15, wherein the silicon antimony alloy has a carbon concentration of 1×10¹⁷ to 1×10²⁰ atoms per cubic centimeter.

17. The structure of claim 15, wherein the silicon antimony alloy is formed from an epitaxy process using a silicon-containing precursor comprising silane (SiH₄), disilane (Si₂H₆), trisilane (Si₃H₈), tetrasilane (Si₄H₁₀), monochlorosilane (MCS), dichlorosilane (DCS), trichlorosilane (TCS), hexachlorodisilane (HODS), octachlorotrisilane (OCTS), silicon tetrachloride (STC), or any combination thereof, and an antimony-containing precursor comprising stibine (SbH₃), antimony trichloride (SbCl₃), antimony tetrachloride (SbCl₄), antimony pentachloride (SbCl₅), triphenylantimony ((C₆H₅)₃Sb), antimony trihydide (SbH₃), antimonytrioxide (Sb₂O₃), antimony pentoxide (Sb₂O₅), antimony trifluoride (SbF₃), antimony tribromide (SbBr₃), antimonytriiodide (SbI₃), antimony pentafluoride (SbF₅), Triethyl antimony (TESb), or trimethyl antimony (TMSb).

18. The structure of claim 17, wherein the silicon antimony alloy is formed from an antimony-containing precursor comprising Triethyl antimony (TESb) or trimethyl antimony (TMSb).

19. The structure of claim 15, wherein the silicon antimony alloy is formed by an epitaxial process.

20. The structure of claim 15, wherein the silicon antimony alloy is formed by an implantation process.
